(19) United States
(12) Patent Application Publication
(10) Pub. No.: US 2011/0057321 A1
(43) Pub. Date: Mar. 10, 2011

(54) 3-D MULTI-WAFER STACKED SEMICONDUCTOR STRUCTURE AND METHOD FOR MANUFACTURING THE SAME

(75) Inventors: Sum-Min Wang, Penghu County (TW); Shih-Hui Wang, Taipei City (TW); Dun-Ying Shu, Hsinchu County (TW); Chwan-Ying Lee, Hsinchu City (TW)

(73) Assignee: INDUSTRIAL TECHNOLOGY RESEARCH INSTITUTE, Hsin-Chu (TW)

(21) Appl. No.: 12/868,241

(22) Filed: Aug. 25, 2010

(30) Foreign Application Priority Data
Sep. 8, 2009 (TW) 098130173

(51) Int. Cl. H01L 23/48; H01L 21/768

(52) U.S. Cl. 257/774; 438/459; 438/675; 257/E23.011; 257/E21.597

(57) ABSTRACT

A 3-D multi-wafer stacked semiconductor structure and method for manufacturing the same. The method comprises steps of: providing a first wafer, a first circuit layer being formed on a surface thereof; bonding the first circuit layer with a carrier; performing a first thinning process on the first wafer; forming a first mask on the other surface of the thinned first wafer; providing a second wafer, a second circuit layer being formed on a surface thereof; bonding the second circuit layer with the first mask; and forming at least a through via filled with a conductor to electrically connect a first connecting pad on the first circuit layer and a second connecting pad on the second circuit layer.

### CROSS-REFERENCE TO RELATED APPLICATION

This non-provisional application claims priority under 35 U.S.C. §119(a) on Patent Application No(s). 098130173 filed in Taiwan, R.O.C. on Sep. 8, 2009, the entire contents of which are hereby incorporated by reference.

### TECHNICAL FIELD

The disclosure generally relates to a 3-D multi-wafer stacked semiconductor structure and a method for manufacturing the same and, more particularly, to a 3-D multi-wafer stacked semiconductor structure and a manufacturing method thereof by etching to form through vias to achieve signal transmission in the multi-wafer stacked semiconductor structure.

### TECHNICAL BACKGROUND

The electronic products have been developed to be miniatured with high performances, high integration and wireless capability. Three-dimensional integrated circuits (3-D IC's) have been considered the next-generation semiconductor technology because they use a 3-D multi-wafer stacked semiconductor structure to shorten the length of the metal leads with lowered resistance and reduce the chip area with lowered cost and power consumption. The 3-D IC's are sensitive to the reliability of the circuitry. The 3-D IC's are characterized in that various chips with different functions can be integrated in one package with the use of through vias.

FIG. 1 is a cross-sectional view of a 3-D semiconductor structure in U.S. Pat. No. 6,410,431, using multi-step Cu-to-Cu bonding in 3-D multi-wafer stacking. In FIG. 1, a dielectric layer 114 (for example, a silicon-nitride layer (SiN)) is deposited over other existing dielectric layers, such as silicon-oxide (SiO) layer 111, SiN layer 112 and SiO layer 113 to act as a barrier layer. The contact pads 12 are then exposed through an etching process and a first sacrificial insulation layer 13 is deposited to define the height of the smallest chip-to-chip connector 10B. Via holes 131 are then etched into the first sacrificial insulation layer 13 and copper 132 is plated to the surface of the via hole 131. The sacrificial insulation 13 undergoes a chemical mechanical polish (CMP), and a second sacrificial insulation layer 14 is deposited thereupon. A first solder layer 141 is formed in the second sacrificial insulation layer 14. A via hole is etched wherein a solder layer of uniform thickness 75 is plated. A second, taller chip-to-chip connector 10A is then similarly fabricated by depositing a third sacrificial layer 15, etching via hole 151, plating the hole with copper plating 152, depositing a fourth sacrificial layer 16 and plating a second solder layer 161. All sacrificial insulating layers are then removed, with dielectric layer 14, or optionally dielectric layer 13 acting as an etch stop.

FIG. 2A and FIG. 2B are cross-sectional views of a 3-D semiconductor structure having a cone-shaped through via in U.S. Pat. No. 7,081,408, using a two-step exposure process and etching to define via holes with different depths and sizes. In FIG. 2A, the photo-resist layer 210 is developed to create a first aperture 215 with a first diameter 216 in the first photo-resist layer 215, wherein the first aperture 215 has a tapered periphery 217. The second photo-resist layer 220 is developed to create a second aperture 225 having a diameter 226 and a tapered periphery 227. The first diameter 216 of the first aperture 215 is smaller than the second diameter 226 of second aperture 225. The tapered periphery 217 of the first aperture 215 lies within the tapered periphery 227 of the second aperture 225. In another embodiment, in FIG. 2B, the via 230 extends through the wafer 205 and down to the conductor 265 of the interconnect structure 260. The via 230 includes a lower zone 239a and an upper zone 239b, as well as a transition region 239t between the lower and upper zones 239a and 239b. The shape and profile of the lower zone 239a is dictated by the tapered periphery 217 of the aperture 215 in first photo-resist layer 210 and/or by the receding first photo-resist layer 210. The shape and profile of the upper zone 239b is dictated by the tapered periphery 227 of the second aperture 225 in second photo-resist layer 220.

FIG. 3A to FIG. 3F are cross-sectional views showing steps for manufacturing a 3-D semiconductor structure having through vias in U.S. Pat. Pub. No. 2008/0079121, using polymer as an insulating layer to manufacture through vias by spacer etching. In FIG. 3A, a photo-resist layer 315 is applied on a wafer 310, which can be used to make several semiconductor chips having through vias or through vias forming regions. Through conducting exposure and development processes for the photo-resist layer 315, a first photo-resist pattern 320 for exposing the regions 328 is formed on each chip. By etching the exposed regions 328 using the first photo-resist pattern 320 as an etch mask, one or more grooves 330 are defined and formed by etching as shown in FIG. 3A. In FIG. 3B, after the first photo-resist pattern 320 is used as an etch mask, it is removed by conducting a conventional process, such as O2 plasma etching. Then, a liquid polymer 340 is applied on the wafer 310 including the grooves 330 in the silicon wafer 310, as a material that forms an insulation layer 340a. Then, in FIG. 3C, through patterning the liquid polymer 340 applied in the grooves 330 in the silicon wafer 310, a polymer insulation layer 340a is formed, i.e., left remaining on the surface of the sidewall 341 of each groove 330 in the silicon wafer 310. In FIG. 3D, a thin film seed metal layer 350 is deposited on the wafer 310 to cover the sidewall 341 in each groove 330. Next, a second photo-resist pattern 360 for defining metal layer forming regions is formed on the seed metal layer 350 to expose the grooves 330 and areas surrounding the grooves 330. Then, in FIG. 3E, using a process such as electroplating, a metal layer 370 is plated onto portions of the seed metal layer 35. Then, the second photo-resist pattern 360 and the seed metal layer 350 are sequentially removed as shown in FIG. 3F. At last, the wafer 310 is thinned to form a through via.

Therefore, this disclosure provides a 3-D multi-wafer stacked semiconductor structure and a method for manufacturing the same by wafer bonding using polymer masks or solid-state masks with an adhesive at a lower temperature and by etching to form through vias to achieve signal transmission in the multi-wafer stacked semiconductor structure.

### SUMMARY

This disclosure provides a 3-D multi-wafer stacked semiconductor structure and a method for manufacturing the same by wafer bonding using polymer masks or solid-state masks with an adhesive and etching to form through vias to achieve signal transmission in the multi-wafer stacked semiconductor structure without reliability issues due to misalignment.

This disclosure provides a 3-D multi-wafer stacked semiconductor structure and a method for manufacturing the same by wafer bonding using polymer masks or solid-state masks with an adhesive and etching to form through vias to achieve signal transmission in the multi-wafer stacked semiconductor structure at a lower temperature and thus higher yield.

In one embodiment, this disclosure provides a method for manufacturing a 3-D multi-wafer stacked semiconductor structure, comprising steps of: providing a first wafer, a first circuit layer being formed on a surface thereof; bonding the first circuit layer with a carrier; performing a first thinning process on the first wafer; forming a first mask on the other surface of the thinned first wafer; providing a second wafer, a second circuit layer being formed on a surface thereof; bonding the second circuit layer with the first mask; and forming at least a through via filled with a conductor to electrically connect a first connecting pad on the first circuit layer and a second connecting pad on the second circuit layer.

In another embodiment, this disclosure provides a method for manufacturing a 3-D multi-wafer stacked semiconductor structure, comprising steps of: providing a first wafer, a first circuit layer being formed on a surface thereof; bonding the first circuit layer with a carrier; performing a first thinning process on the first wafer; forming a first mask on the other surface of the thinned first wafer; providing a second wafer, a second circuit layer being formed on a surface thereof; bonding the second circuit layer with the first mask; performing a second thinning process on the second wafer; forming a second mask on the other surface of the thinned second wafer; providing a third wafer, a third circuit layer being formed on a surface thereof; bonding the third circuit layer with the second mask; and forming at least a first through via filled with a conductor to electrically connect a first connecting pad on the first circuit layer and a third connecting pad on the third circuit layer, and at least a second through via filled with the conductor to electrically couple the first connecting pad on the first circuit layer and a second connecting pad on the second circuit layer.

In another embodiment, this disclosure provides a 3-D multi-wafer stacked semiconductor structure, comprising: a first wafer, a first circuit layer being formed on a surface thereof; a first mask formed on the other surface of the first wafer; a second wafer, a second circuit layer being formed on a surface thereof, the second circuit layer being bonded with the first mask; and at least a through via filled with a conductor to electrically connect a first connecting pad on the first circuit layer and a second connecting pad on the second circuit layer.

In another embodiment, this disclosure provides a 3-D multi-wafer stacked semiconductor structure, comprising: a first wafer, a first circuit layer being formed on a surface thereof; a first mask formed on the other surface of the first wafer; a second wafer, a second circuit layer being formed on a surface thereof, the second circuit layer being bonded with the first mask; a second mask formed on the other surface of the second wafer; a third wafer, a third circuit layer being formed on a surface thereof, the third circuit layer being bonded with the second mask; and at least a first through via filled with a conductor to electrically connect a first connecting pad on the first circuit layer and a third connecting pad on the third circuit layer, and at least a second through via filled with a conductor to electrically connect the first connecting pad on the first circuit layer and a second connecting pad on the second circuit layer.

### BRIEF DESCRIPTION OF THE DRAWINGS

The embodiments of this disclosure will be readily understood by the accompanying drawings and detailed descriptions, wherein:

FIG. 1 is a cross-sectional view of a 3-D semiconductor structure in U.S. Pat. No. 6,410,431;

FIG. 2A and FIG. 2B are cross-sectional views of a 3-D semiconductor structure having a cone-shaped through via in U.S. Pat. No. 7,081,408;

FIG. 3A to FIG. 3F are cross-sectional views showing steps for manufacturing a 3-D semiconductor structure having through vias in U.S. Pat. Pub. No. 2008/0079121;

FIG. 4A to FIG. 4I are cross-sectional views showing steps for manufacturing a 3-D multi-wafer stacked semiconductor structure according to one embodiment of this disclosure;

FIG. 5 is a top view of a 3-D multi-wafer stacked semiconductor structure of this disclosure; and

FIG. 6A to FIG. 6I are cross-sectional views showing steps for forming through vias in a 3-D multi-wafer stacked semiconductor structure according to one embodiment of this disclosure.

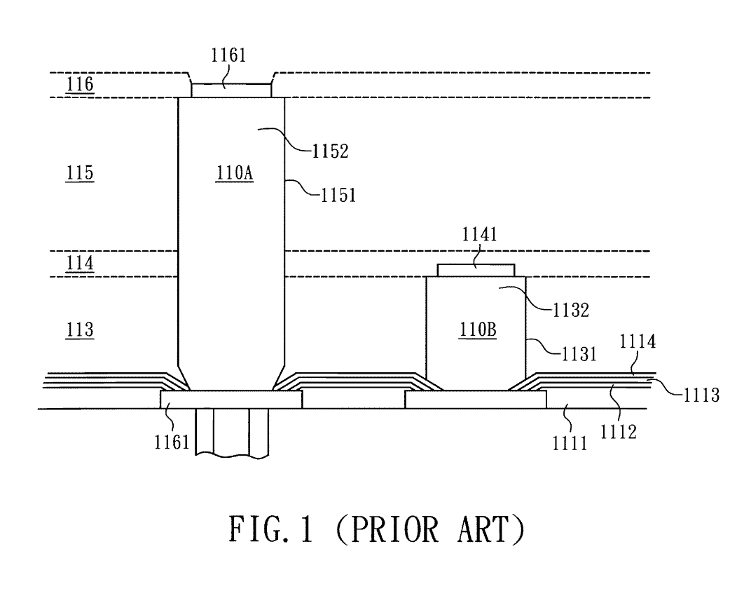

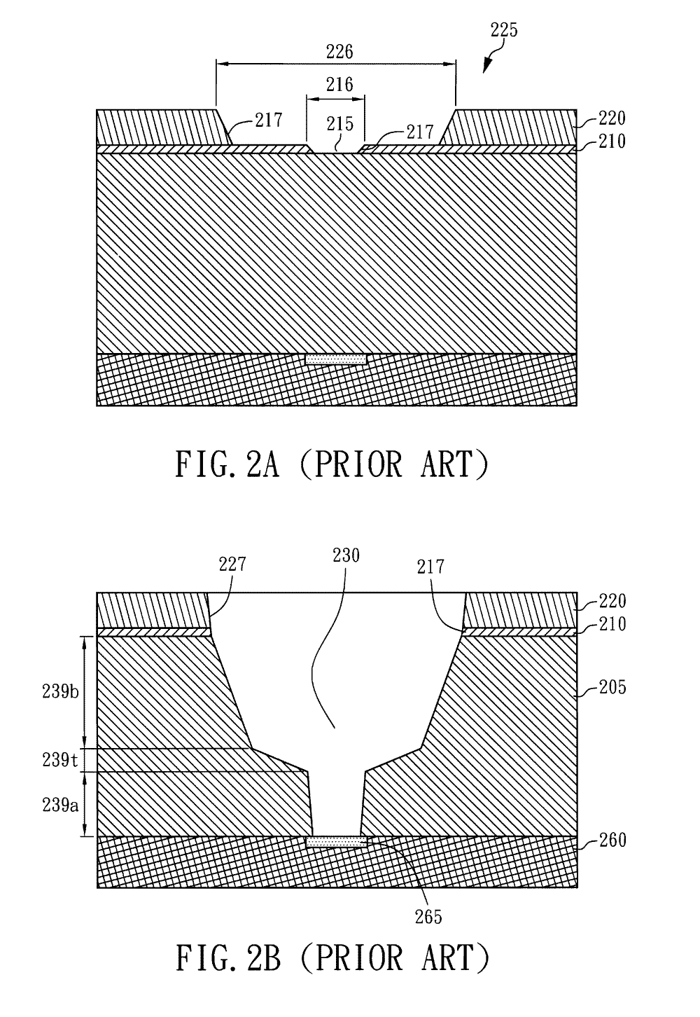

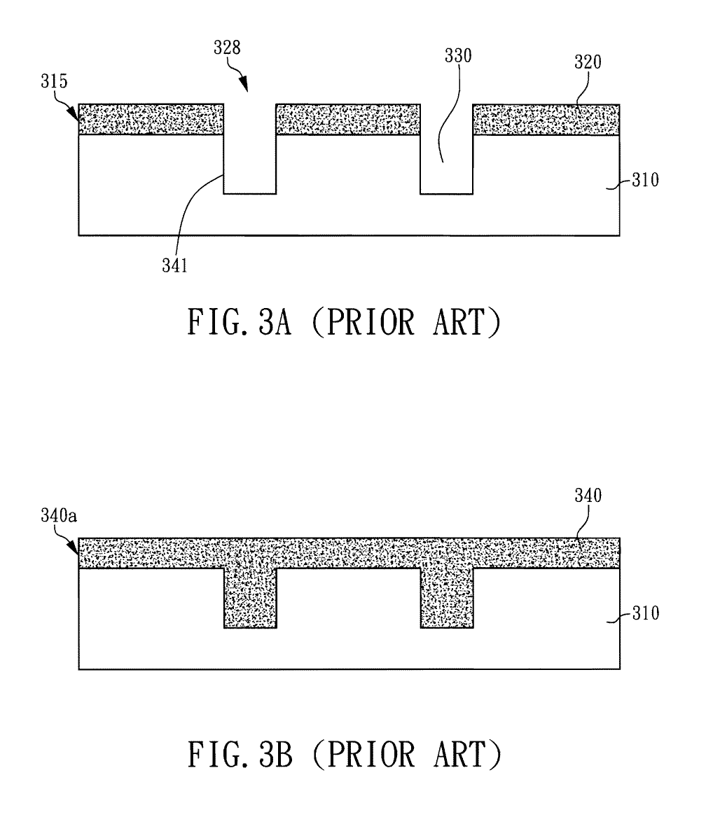

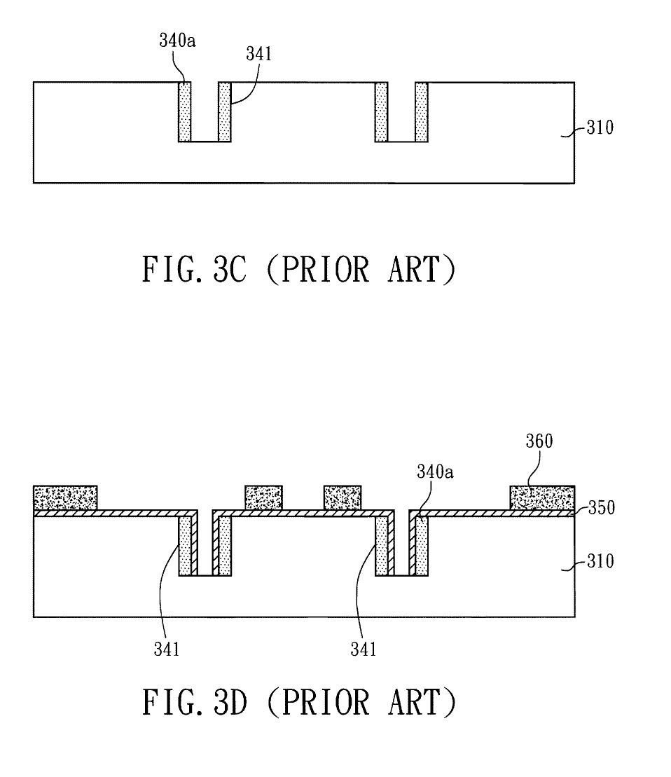

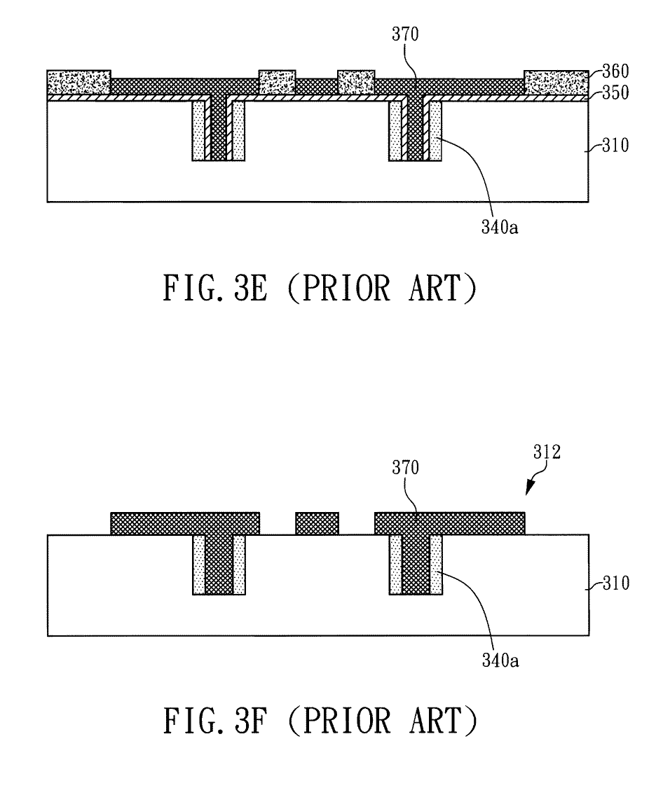

### DETAILED DESCRIPTION OF EMBODIMENTS

This disclosure can be exemplified but not limited by various embodiments as described hereinafter.

In this disclosure, a 3-D multi-wafer stacked semiconductor structure and a method for manufacturing the same are provided by wafer bonding using polymer masks or solid-state masks with an adhesive at a lower temperature and by etching to form through vias to achieve signal transmission in the multi-wafer stacked semiconductor structure.

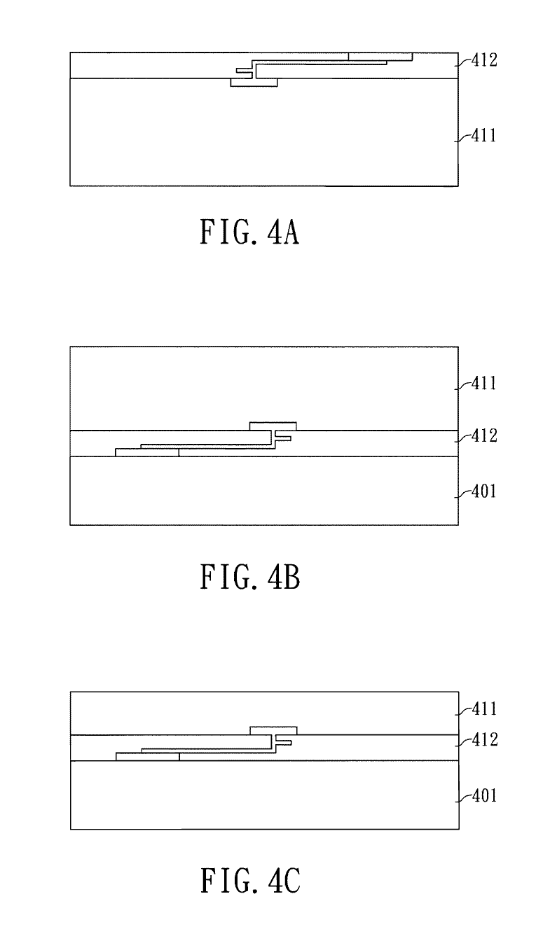

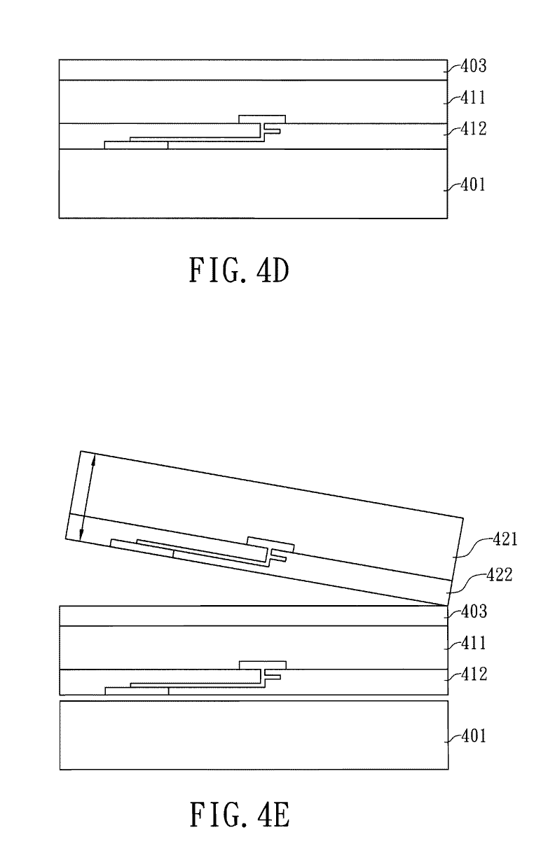

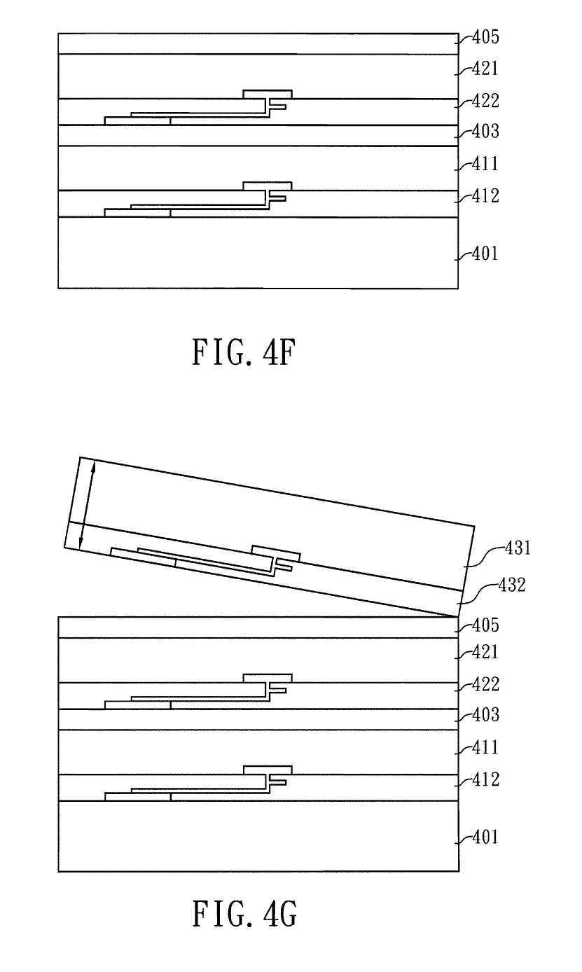

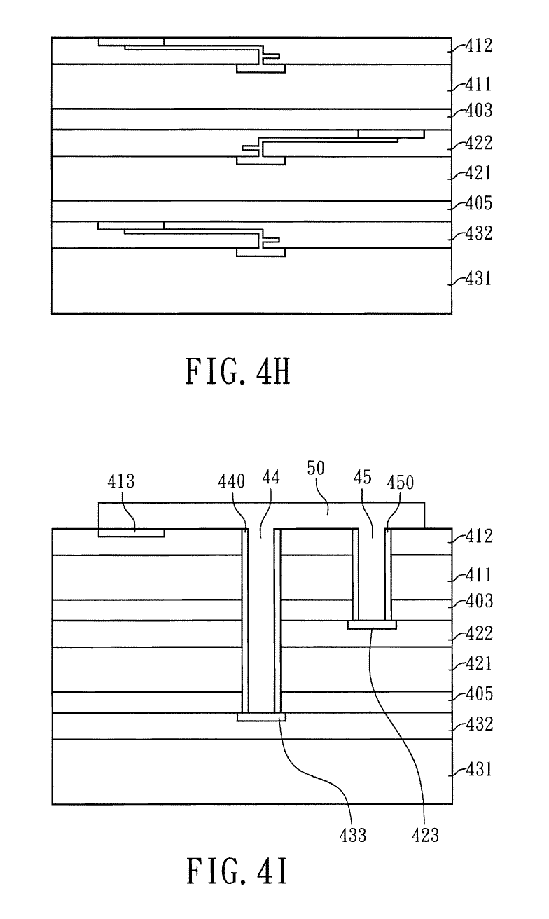

FIG. 4A to FIG. 4I are cross-sectional views showing steps for manufacturing a 3-D multi-wafer stacked semiconductor structure according to one embodiment of this disclosure. In FIG. 4A, a first wafer 411 is provided so that a first circuit layer 412 is formed on a surface thereof. Then, in FIG. 4B, the first circuit layer 412 is bonded with a carrier 401. In FIG. 4C, a first thinning process is performed on the first wafer 411. Then, in FIG. 4D, a first mask 403 is formed on the other surface of the thinned first wafer 411. In FIG. 4E, a second wafer 421 is provided so that a second circuit layer 422 is formed on a surface thereof. The second circuit layer 422 is bonded with the first mask 403. Then, in FIG. 4F, a second thinning process is performed on the second wafer 421. A second mask 405 is formed on the other surface of the thinned second wafer 421. In FIG. 4G, a third wafer 431 is provided so that a third circuit layer 432 is formed on a surface thereof. The third circuit layer 432 is bonded with the second mask 405. In FIG. 4H, the carrier 401 is removed. At last, at least a first through via 44 is formed filled with a conductor 50 to electrically connect a first connecting pad 413 on the first circuit layer 412 and a third connecting pad 433 on the third circuit layer 432. Similarly, at least a second through via 45 is formed filled with the conductor 50 to electrically couple the first connecting pad 413 on the first circuit layer 412 and a second connecting pad 423 on the second circuit layer 422.

In the present embodiment, the first wafer 411, the second wafer 421 and the third wafer 431 may comprise any semiconductor material, such as, silicon (Si), gallium arsenide (GaAs), gallium nitride (GaN), indium phosphide (InP), sapphire, glass, etc. However, it is readily understood by anyone with ordinary skill in the art that this disclosure is not limited to the disclosed materials.

In the present embodiment, the first thinning process and the second thinning process is may be performed by polishing or etching, such as, mechanical polishing, chemical-mechanical polishing (CMP), wet etching or dry etching. However, it is readily understood by anyone with ordinary skill in the art that this disclosure is not limited to the disclosed methods.

In the present embodiment, the first mask 403 and the second mask 405 is may be patterned or non-patterned.

In the present embodiment, the first mask 403 and the second mask 405 are polymer masks or solid-state masks with an adhesive. The solid-state mask may comprise oxide, nitride or a mixture thereof. However, it is readily understood by anyone with ordinary skill in the art that this disclosure is not limited to the disclosed materials.

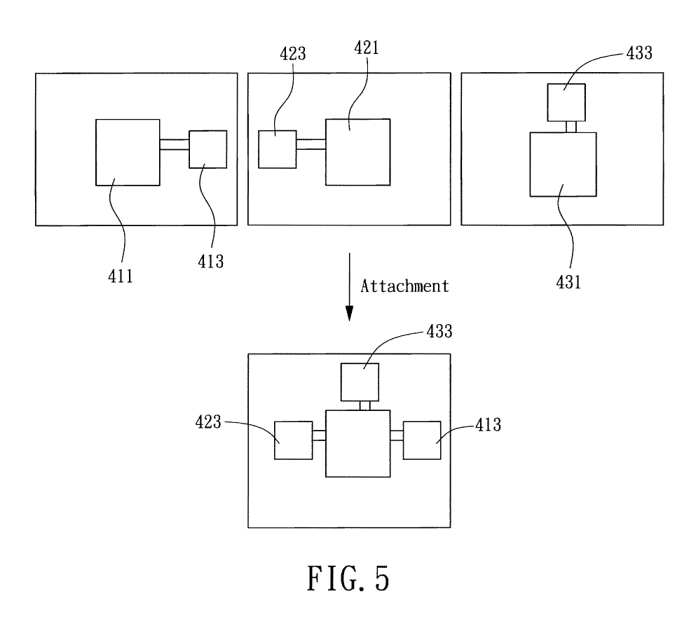

FIG. 5 is a top view of a 3-D multi-wafer stacked semiconductor structure of this disclosure. It is obvious that chips with various functions or purposes can be integrated onto a circuit board by the use of the method in this disclosure to significantly improve the performances and flexibility of the 3-D IC's.

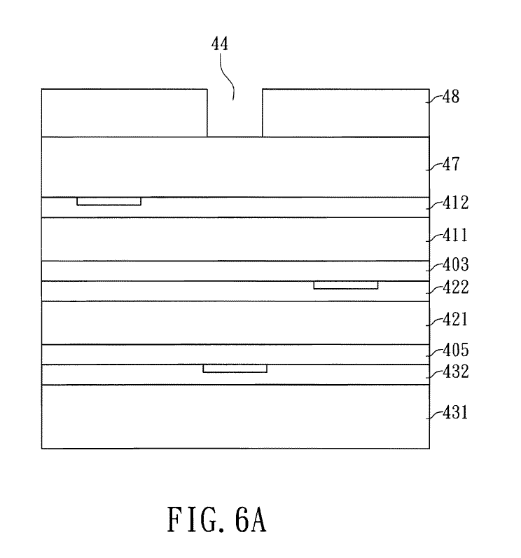

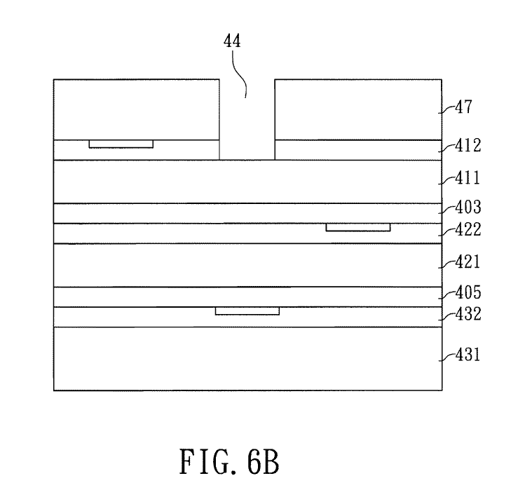

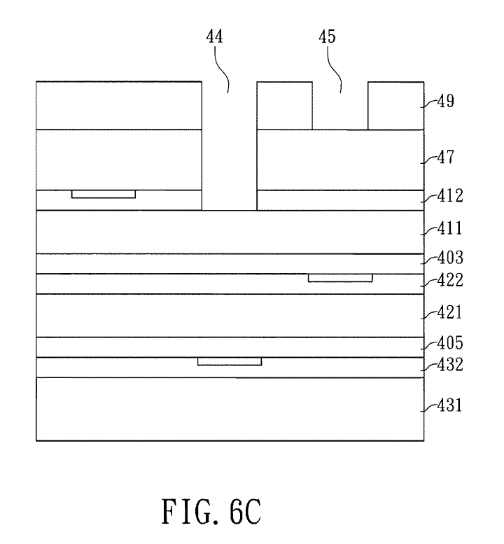

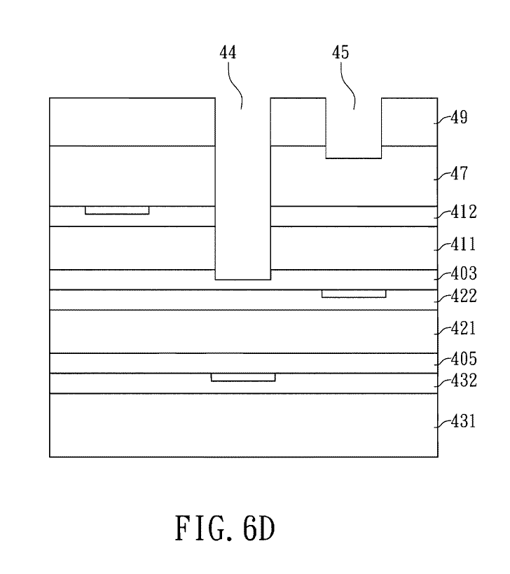

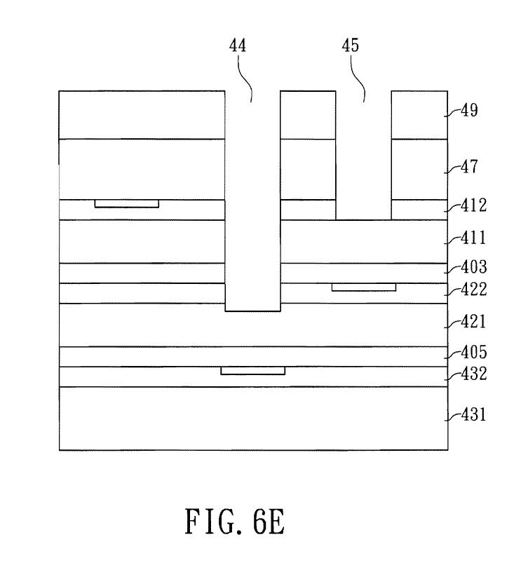

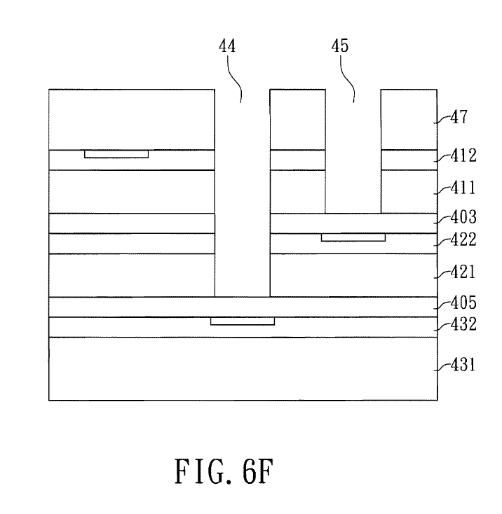

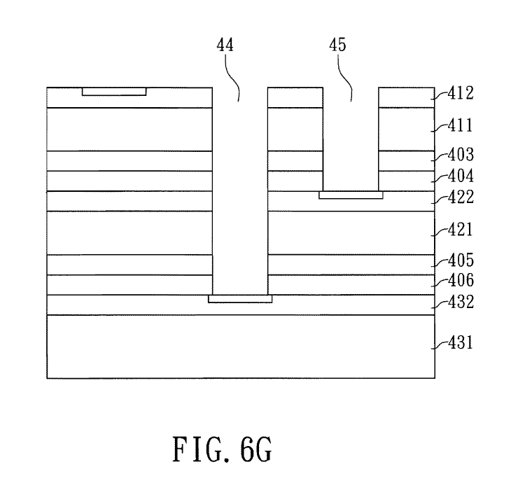

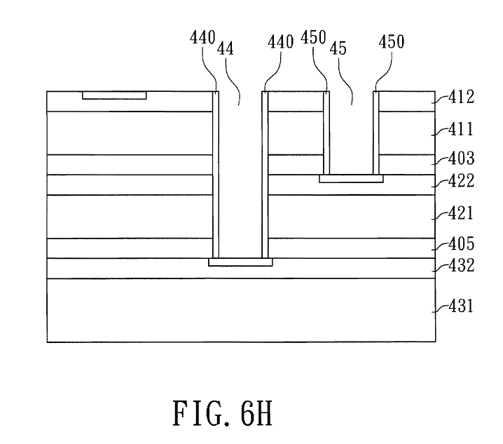

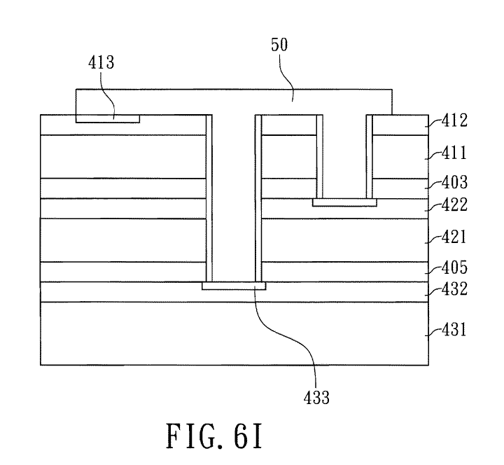

FIG. 6A to FIG. 6I are cross-sectional views showing steps for forming through vias in a 3-D multi-wafer stacked semiconductor structure according to one embodiment of this disclosure. Firstly, in FIG. 6A, a cap layer 47 is provided on the first circuit layer 412 so that a first patterned photo-resist layer 48 is formed on the cap layer 47. The first patterned photo-resist layer 48 is provided with a first opening 44 to expose the cap layer 47. Then, in FIG. 6B, the cap layer 47 and the first circuit layer 412 in the first opening 44 are removed to expose the first wafer 411. Then, the first patterned photo-resist layer 48 is removed and a second patterned photo-resist layer 49 is formed on the cap layer 47, as shown in FIG. 6C. The second patterned photo-resist layer 49 is provided with a second opening 44 and a third opening 45. The second opening 44 in second patterned photo-resist layer 49 is aligned with the first opening 44 in the first patterned photo-resist layer 48, and the third opening 45 in the second patterned photo-resist layer 49 exposes the cap layer 47. In FIG. 6D, the first wafer 411 in the second opening 44 is removed to expose the first mask 403. In FIG. 6E, the first mask 403 and the second circuit layer 422 in the second opening 44 are removed to expose the second wafer 421. The cap layer 47 and the first circuit layer 412 in the third opening 45 are removed to expose the first wafer 411. Then, in FIG. 6F, the second wafer 421 in the second opening 44 is removed to expose the second mask 405. The first wafer 411 in the third opening 45 is removed to expose the first mask 403. In FIG. 6G, the second mask 405 in the second opening 44 is removed to expose the third connecting pad 433 on the third circuit layer 432, and the first mask 403 in the third opening 45 is removed to expose the second connecting pad 423 on the second circuit layer 422. Then, in FIG. 6H, an insulating layer is formed, and an etchback process is performed on the insulating layer to form a first spacer 440 on a sidewall surface of the second opening 44a and a second spacer 450 on a sidewall surface of the third opening 45a. At last, a conductor 50 is formed filling the second opening 44 to electrically couple a first connecting pad 413 on the first circuit layer 412 and a third connecting pad 433 on the third circuit layer 432 and filling the third opening 45 to electrically couple the first connecting pad 413 on the first circuit layer 412 and the second connecting pad 423 on the second circuit layer 422, as shown in FIG. 6I.

In the present embodiment, the first wafer 411, the second wafer 421 and the third wafer 431 may comprise any semiconductor material, such as, silicon (Si), gallium arsenide (GaAs), gallium nitride (GaN), indium phosphide (InP), sapphire, glass, etc. However, it is readily understood by anyone with ordinary skill in the art that this disclosure is not limited to the disclosed materials.

In the present embodiment, the first thinning process and the second thinning process is may be performed by polishing or etching, such as, mechanical polishing, chemical-mechanical polishing (CMP), wet etching or dry etching. However, it is readily understood by anyone with ordinary skill in the art that this disclosure is not limited to the disclosed methods.

In the present embodiment, the first mask 403 and the second mask 405 is may be patterned or non-patterned.

In the present embodiment, the first mask 403 and the second mask 405 are polymer masks or solid-state masks with an adhesive. The solid-state mask may comprise oxide, nitride or a mixture thereof. However, it is readily understood by anyone with ordinary skill in the art that this disclosure is not limited to the disclosed materials.

In the present embodiment, the cap layer 47 may comprise oxide, nitride or a mixture thereof. The insulating layer for forming the spacers 440 and 450 may comprise polymer, oxide, nitride or a mixture thereof.

Even though the structures in FIG. 4A to FIG. 4I, FIG. 5A and FIG. 6A to FIG. 61 are three-wafered structures. This disclosure is not limited to the number of wafers to be stacked. For example, after the step in FIG. 4E is completed, the carrier 401 can be removed so that at least a through via can be formed filled with a conductor to electrically couple a first connecting pad 413 on the first circuit layer 412 and a second connecting pad 423 on the second circuit layer 422. Similarly, a 3-D multi-wafer stacked structure having other numbers of wafers can be implemented by the use of this disclosure. Thus, it is readily understood by anyone with ordinary skill in the art that this disclosure is not limited to the number of wafers.

Moreover, the step in FIG. 4H may also be omitted. In other words, the carrier 401 does not need to be removed. Instead, the carrier 401 can replace the cap layer 47 in the step in FIG. 6A. Therefore, it is readily understood by anyone with ordinary skill in the art that this disclosure is not limited by the foregoing embodiments.

Accordingly, this disclosure provides a 3-D multi-wafer stacked semiconductor structure and a method for manufacturing the same by wafer bonding using polymer masks or solid-state masks with an adhesive at a lower temperature to improve yield and by etching to form through vias to achieve signal transmission in the multi-wafer stacked semiconductor structure without reliability issues due to misalignment. Therefore, this disclosure is useful, novel and non-obvious.

Although this disclosure has been disclosed and illustrated with reference accelerometer to particular embodiments, the principles involved are susceptible for use in numerous other embodiments that will be apparent to persons skilled in the art. This disclosure is, therefore, to be limited only as indicated by the scope of the appended claims.

What is claimed is:

1. A method for manufacturing a 3-D multi-wafer stacked semiconductor structure, comprising steps of:
providing a first wafer, a first circuit layer being formed on a surface thereof;
bonding the first circuit layer with a carrier;
performing a first thinning process on the first wafer;
forming a first mask on the other surface of the thinned first wafer;
providing a second wafer, a second circuit layer being formed on a surface thereof;
bonding the second circuit layer with the first mask; and
forming at least a through via filled with a conductor to electrically connect a first connecting pad on the first circuit layer and a second connecting pad on the second circuit layer.

2. The method for manufacturing a 3-D multi-wafer stacked semiconductor structure as recited in claim 1, wherein the step of forming at least a through via further comprises steps of:
removing the carrier;
providing a cap layer on the first circuit layer;
forming a patterned photo-resist layer on the cap layer, the patterned photo-resist layer being provided with an opening to expose the cap layer;
removing the cap layer and the first circuit layer in the opening;
removing the first wafer in the opening to expose the first mask;
removing the patterned photo-resist layer and the cap layer, and removing the first mask in the opening to expose the second connecting pad on the second circuit layer;
forming an insulating layer and performing an etchback process on the insulating layer to form a spacer on a sidewall surface of the opening; and
forming a conductor filling the opening so that the first connecting pad on the first circuit layer and the second connecting pad on the second circuit layer are electrically coupled.

3. The method for manufacturing a 3-D multi-wafer stacked semiconductor structure as recited in claim 2, wherein the first mask is a polymer mask or a solid-state mask with an adhesive.

4. The method for manufacturing a 3-D multi-wafer stacked semiconductor structure as recited in claim 2, wherein the cap layer comprises polymer, oxide, nitride or a mixture thereof.

5. The method for manufacturing a 3-D multi-wafer stacked semiconductor structure as recited in claim 2, wherein the insulating layer comprises polymer, oxide, nitride or a mixture thereof.

6. The method for manufacturing a 3-D multi-wafer stacked semiconductor structure as recited in claim 1, wherein the step of forming at least a through via further comprises steps of:
forming a patterned photo-resist layer on the carrier, the patterned photo-resist layer being provided with an opening to expose the carrier;
removing the carrier and the first circuit layer in the opening;
removing the first wafer in the opening to expose the first mask;
removing the patterned photo-resist layer and the carrier, and removing the first mask in the opening to expose the second connecting pad on the second circuit layer;
forming an insulating layer and performing an etchback process on the insulating layer to form a spacer on a sidewall surface of the opening; and
forming a conductor filling the opening so that the first connecting pad on the first circuit layer and the second connecting pad on the second circuit layer are electrically coupled.

7. The method for manufacturing a 3-D multi-wafer stacked semiconductor structure as recited in claim 6, wherein the first mask is a polymer mask or a solid-state mask with an adhesive.

8. The method for manufacturing a 3-D multi-wafer stacked semiconductor structure as recited in claim 6, wherein the carrier comprises polymer, oxide, nitride or a mixture thereof.

9. The method for manufacturing a 3-D multi-wafer stacked semiconductor structure as recited in claim 6, wherein the insulating layer comprises polymer, oxide, nitride or a mixture thereof.

10. A method for manufacturing a 3-D multi-wafer stacked semiconductor structure, comprising steps of:
providing a first wafer, a first circuit layer being formed on a surface thereof;
bonding the first circuit layer with a carrier;
performing a first thinning process on the first wafer;
forming a first mask on the other surface of the thinned first wafer;
providing a second wafer, a second circuit layer being formed on a surface thereof;
bonding the second circuit layer with the first mask;
performing a second thinning process on the second wafer;
forming a second mask on the other surface of the thinned second wafer;
providing a third wafer, a third circuit layer being formed on a surface thereof;
bonding the third circuit layer with the second mask; and
forming at least a first through via filled with a conductor to electrically connect a first connecting pad on the first circuit layer and a third connecting pad on the third circuit layer, and at least a second through via filled with the conductor to electrically couple the first connecting pad on the first circuit layer and a second connecting pad on the second circuit layer.

11. The method for manufacturing a 3-D multi-wafer stacked semiconductor structure as recited in claim 10, wherein the step of forming at least a first through via and a second through via further comprises steps of:
removing the carrier;
providing a cap layer on the first circuit layer;
forming a first patterned photo-resist layer on the cap layer, the first patterned photo-resist layer being provided with a first opening to expose the cap layer;
removing the cap layer and the first circuit layer in the first opening to expose the first wafer;
removing the first patterned photo-resist layer and forming a second patterned photo-resist layer on the cap layer, the second patterned photo-resist layer being provided with a second opening and a third opening, wherein the second opening in the second patterned photo-resist layer is aligned with the first opening in the first patterned photo-resist layer and the third opening in the second patterned photo-resist layer exposes the cap layer;
removing the first wafer in the second opening to expose the first mask;
removing the first mask and the second circuit layer in the second opening to expose the second wafer, and removing the cap layer and the first circuit layer in the third opening to expose the first wafer;
removing the second wafer in the second opening to expose the second mask, and removing the first wafer in the third opening to expose the first mask;
removing the second mask in the second opening to expose the third connecting pad on the third circuit layer, and removing the first mask in the third opening to expose the second connecting pad on the second circuit layer;
forming an insulating layer and performing an etchback process on the insulating layer to form a first spacer on a sidewall surface of the second opening and a second spacer on a sidewall surface of the third opening; and
forming a conductor filling the second opening to electrically couple a first connecting pad on the first circuit layer and a third connecting pad on the third circuit layer, and filling the third opening to electrically couple the first connecting pad on the first circuit layer and the second connecting pad on the second circuit layer.

12. The method for manufacturing a 3-D multi-wafer stacked semiconductor structure as recited in claim 11, wherein the first mask and the second mask are polymer masks or solid-state masks with an adhesive.

13. The method for manufacturing a 3-D multi-wafer stacked semiconductor structure as recited in claim 11, wherein the cap layer comprises polymer, oxide, nitride or a mixture thereof.

14. The method for manufacturing a 3-D multi-wafer stacked semiconductor structure as recited in claim 11, wherein the insulating layer comprises polymer, oxide, nitride or a mixture thereof.

15. The method for manufacturing a 3-D multi-wafer stacked semiconductor structure as recited in claim 10, wherein the step of forming at least a first through via and a second through via further comprises steps of:
forming a first patterned photo-resist layer on the carrier, the first patterned photo-resist layer being provided with a first opening to expose the carrier;
removing the carrier and the first circuit layer in the first opening to expose the first wafer;
removing the first patterned photo-resist layer and forming a second patterned photo-resist layer on the carrier, the second patterned photo-resist layer being provided with a second opening and a third opening, wherein the second opening in the second patterned photo-resist layer is aligned with the first opening in the first patterned photo-resist layer and the third opening in the second patterned photo-resist layer exposes the carrier;
removing the first wafer in the second opening to expose the first mask;
removing the first mask and the second circuit layer in the second opening to expose the second wafer, and removing the carrier and the first circuit layer in the third opening to expose the first wafer;
removing the second wafer in the second opening to expose the second mask, and removing the first wafer in the third opening to expose the first mask;
removing the second mask in the second opening to expose the third connecting pad on the third circuit layer, and removing the first mask in the third opening to expose the second connecting pad on the second circuit layer;
forming an insulating layer and performing an etchback process on the insulating layer to form a first spacer on a sidewall surface of the second opening and a second spacer on a sidewall surface of the third opening; and
forming a conductor filling the second opening to electrically couple a first connecting pad on the first circuit layer and a third connecting pad on the third circuit layer, and filling the third opening to electrically couple the first connecting pad on the first circuit layer and the second connecting pad on the second circuit layer.

16. The method for manufacturing a 3-D multi-wafer stacked semiconductor structure as recited in claim 15, wherein the first mask and the second mask are polymer masks or solid-state masks with an adhesive.

17. The method for manufacturing a 3-D multi-wafer stacked semiconductor structure as recited in claim 15, wherein the carrier comprises polymer, oxide, nitride or a mixture thereof.

18. The method for manufacturing a 3-D multi-wafer stacked semiconductor structure as recited in claim 15, wherein the insulating layer comprises polymer, oxide, nitride or a mixture thereof.

19. A 3-D multi-wafer stacked semiconductor structure, comprising:
a first wafer, a first circuit layer being formed on a surface thereof;
a first mask formed on the other surface of the first wafer;
a second wafer, a second circuit layer being formed on a surface thereof, the second circuit layer being bonded with the first mask; and
at least a through via filled with a conductor to electrically connect a first connecting pad on the first circuit layer and a second connecting pad on the second circuit layer.

20. The 3-D multi-wafer stacked semiconductor structure as recited in claim 19, wherein the first mask is a polymer mask or a solid-state mask with an adhesive.

21. A 3-D multi-wafer stacked semiconductor structure, comprising:
a first wafer, a first circuit layer being formed on a surface thereof;
a first mask formed on the other surface of the first wafer;
a second wafer, a second circuit layer being formed on a surface thereof, the second circuit layer being bonded with the first mask;
a second mask formed on the other surface of the second wafer;
a third wafer, a third circuit layer being formed on a surface thereof, the third circuit layer being bonded with the second mask; and
at least a first through via filled with a conductor to electrically connect a first connecting pad on the first circuit layer and a third connecting pad on the third circuit layer, and at least a second through via filled with a conductor to electrically connect the first connecting pad on the first circuit layer and a second connecting pad on the second circuit layer.

22. The 3-D multi-wafer stacked semiconductor structure as recited in claim 21, wherein the first mask and the second mask are polymer masks or solid-state masks with an adhesive.
